(19) United States
(12) Patent Application Publication
(10) Pub. No.: US 2010/0177615 A1
(43) Pub. Date: Jul. 15, 2010

(54) MAXIMUM LIKELIHOOD DECODER AND INFORMATION REPRODUCTION APPARATUS

(76) Inventor: Akira Yamamoto, Osaka (JP)

Correspondence Address: MCDERMOTT WILL & EMERY LLP, 600 13TH STREET, NW, WASHINGTON, DC, 20005-3096, US

(21) Appl. No.: 12/278,238

(22) PCT Filed: Oct. 15, 2007
(86) PCT No.: PCT/JP2007/070087

§ 371 Date: Aug. 4, 2008

(30) Foreign Application Priority Data
Feb. 21, 2007 (JP) 2007-041000

(51) Int. Cl. G11B 20/10; H03M 13/03

(52) U.S. Cl. 369/59.22; 714/794; G9B/5.033

(57) ABSTRACT

In a maximum likelihood decoder, when undersampling occurs, selectors 205 to 207 do not select branch metrics from branch metric calculation sections 202 to 204 but select a value “0”, and a path metric calculation section 208 calculates a path metric based on the value “0” selected by the selectors 205 to 207, while calculating a path selection signal. An input signal wsdt_d, which is input to the branch metric calculation sections 202 to 204 and which is subjected to maximum likelihood decoding, is adjusted, with consideration given to the time of the occurrence of the undersampling at which the selectors 205 to 207 select the value “0”, so as to be a signal delayed by the number of clocks corresponding to that occurrence time. Thus, correct decoding results are obtainable even when the undersampling occurs, thereby ensuring proper operation.

### TECHNICAL FIELD

The present invention relates to a maximum likelihood decoder using the Viterbi algorithm, and an information reproduction apparatus including the maximum likelihood decoder.

### BACKGROUND ART

As this type of maximum likelihood decoder, a maximum likelihood decoder using a synchronous sampling method is conventionally known. In this method, even if a sampling clock is out of phase and of a different frequency in the initial state, the frequency and phase thereof are controlled so that the sampling clock is synchronized with the channel clock.

FIG. 6 illustrates the entire configuration of a maximum likelihood decoder using a synchronous sampling method. In FIG. 6, an input signal wsdt_d, which is to be subjected to maximum likelihood decoding, is input to a plurality of branch metric calculation sections 402 to 404 for calculation of branch metrics. The branch metrics calculated are then input to a path metric calculation section 408, which operates in accordance with a synchronous clock clk and in which a path metric and a path selection signal are calculated. Based on this path selection signal, a survival path control section 409, operating in accordance with the synchronous clock clk, obtains a survival path and outputs a code corresponding to that survival path as a post-decoding data signal.

However, as miniaturization of semiconductor fabrication processes has been advanced and the “X” speed has been increased, it is becoming increasingly difficult year by year to achieve synchronization with the synchronous sampling method.

In view of this, an asynchronous sampling method has been previously proposed in which data is sampled in accordance with an asynchronous clock whose frequency and phase are different from those of the channel clock. This method has an advantage in that data decimation and interpolation are performed within a digital circuit to thereby synchronize the frequency and phase of output data to the channel clock, thus achieving the synchronization with relative easy despite the miniaturized semiconductor fabrication processes and the increased “X” speed. In this method, the frequency of the sampling clock is completely fixed or is controlled to the extent that oversampling can be maintained. Such asynchronous-oversampling-method maximum likelihood decoders are disclosed in Patent Documents 1 and 2, for example.

In the asynchronous oversampling method, if, in FIG. 6, for example, the number of items of output data data exceeds the number of channel bits, the operation of the path metric calculation section 408 and the operation of the survival path control section 409 are temporarily halted so as to make the number of items of output data data equal to the number of channel bits.

### Patent Document 1: Japanese Laid-Open Publication No. 8-251039

### Patent Document 2: WO 06/019073

### DISCLOSURE OF THE INVENTION

### Problem that the Invention Intends to Solve

Nevertheless, the conventional maximum likelihood decoders are both based on the assumption that oversampling is performed and thus have a problem in that if undersampling occurs accidentally, the operation thereof is not performed properly.

In view of the problem with the conventional decoders, it is an object of the present invention to ensure proper operation of an asynchronous-sampling-method maximum likelihood decoder for reproducing data recorded on an optical disk, etc., even if undersampling occurs.

### Means for Solving the Problem

In order to achieve the object, according to the present invention, at the time of a bit slip in which undersampling occurs, branch metrics at that time are forced to be set to a value of 0, and a path selection signal is calculated.

And when the path selection signal is calculated based on the branch metrics having a value of 0, signal supply to the branch metric calculation sections is substantially stopped.

Specifically, an inventive maximum likelihood decoder includes: a branch metric calculation section for receiving a first signal containing recording-timing information, and calculating a branch metric based on the first input signal and on a reference value for use in maximum likelihood decoding; a path selection signal calculation section for calculating a path selection signal based on the branch metric calculated by the branch metric calculation section; a survival path control section for calculating a decoded value by performing maximum likelihood decoding of the first input signal in accordance with the path selection signal calculated by the path selection signal calculation section; and a selecting section for receiving a first selection signal and selecting either the branch metric of the branch metric calculation section or a value “0” in accordance with the first selection signal, wherein the path selection signal calculation section receives either the branch metric of the branch metric calculation section or the value “0” selected by the selecting section, and calculates the path selection signal based on the received branch metric or value “0”.

The inventive maximum likelihood decoder includes a reference value generating section for receiving a first phase signal and generating a reference value for Viterbi decoding in a phase indicated by the first phase signal, in accordance with the first phase signal and reference values in two adjacent zero phases immediately before and after the phase indicated by the first phase signal.

In the inventive maximum likelihood decoder, the branch metric calculation section, the path selection signal calculation section, and the survival path control section receive a second selection signal and change a branch metric calculation method, a path selection signal calculation method, and a decoded-value calculation method in accordance with the second selection signal.

In the inventive maximum likelihood decoder, the first selection signal input to the selecting section is an undersampling signal output when undersampling of recorded data occurs; and the selecting section, upon receipt of the undersampling signal, selects the value “0”.

In the inventive maximum likelihood decoder, the second selection signal is an oversampling signal output when oversampling of recorded data occurs; and the branch metric calculation section, the path selection signal calculation section, and the survival path control section, upon receipt of the oversampling signal, each stop operating.

The inventive maximum likelihood decoder includes a reference value generating section for receiving a first phase signal and generating a reference value for Viterbi decoding in a phase indicated by the first phase signal, in accordance with the first phase signal and reference values in two adjacent zero phases immediately before and after the phase indicated by the first phase signal.

The inventive maximum likelihood decoder includes a controller for receiving a Viterbi decoder control signal and generating the first and second selection signals based on the Viterbi decoder control signal.

The inventive maximum likelihood decoder includes: a timing detecting section for receiving a second signal containing the recording-timing information and a clock signal, outputting, as a second phase signal, a phase difference between the recording-timing information contained in the second input signal and the clock signal in accordance with the second input signal and the clock signal, and generating an overflow signal having a predetermined value each time the second phase signal exceeds a channel cycle indicated by the recording-timing information by one cycle or multiple cycles; and a delay unit for delaying the second input signal and the second phase signal in accordance with a certain amount of delay corresponding to the value of the overflow signal generated by the timing detecting section, and outputting the delayed signals as the first input signal and as a first phase signal, while outputting a Viterbi decoder control signal.

An inventive information reproduction apparatus includes: the maximum likelihood decoder described above; a read section for reading data recorded on a recording medium as an analog signal; an analog waveform shaping section for shaping the analog signal read by the read section; an analog-to-digital converting section for converting the analog signal shaped by the analog waveform shaping section to a digital signal in accordance with timing provided by the clock signal; a clock generating section for receiving a clock control signal and generating the clock signal having a certain cycle based on the clock control signal; and a digital signal shaping section for shaping the digital signal converted by the analog-to-digital converting section and outputting the shaped signal as the second input signal to the timing detecting section, wherein the timing detecting section in the maximum likelihood decoder also generates the clock control signal.

In the inventive information reproduction apparatus, the timing detecting section generates the clock control signal so that the clock signal generated by the clock generating section has a frequency higher than a desired frequency.

In the inventive information reproduction apparatus, the timing detecting section generates the clock control signal so that the clock signal generated by the clock generating section has a frequency equal to a desired frequency.

In the inventive information reproduction apparatus, the delay unit included in the maximum likelihood decoder reduces an amount of delay when the clock signal has a frequency higher than a desired frequency, maintains the amount of delay when the clock signal has a frequency equal to the desired frequency, and increases the amount of delay when the clock signal has a frequency lower than the desired frequency.

In the inventive information reproduction apparatus, the desired frequency is a channel frequency.

In the inventive information reproduction apparatus, the desired frequency is a frequency which is an integral multiple of a channel frequency.

In the inventive information reproduction apparatus, the desired frequency is a frequency which is an integral submultiple of a channel frequency.

In the inventive information reproduction apparatus, the first input signal is a signal reproduced from an optical disk.

In the inventive information reproduction apparatus, the first input signal is a signal reproduced from a magneto-optical disk.

In the inventive information reproduction apparatus, the first input signal is a signal reproduced from a magnetic disk.

As described above, according to the present invention, when undersampling occurs, the branch metric at this point in time is forced to be set to a value of 0, and the path selection signal is calculated based on the branch metric having a value of 0. The calculated path selection signal is interpolated as a path selection signal at the time of the occurrence of the undersampling. Therefore, even when undersampling occurs, it is possible to make the number of items of data equal to the number of channel bits, thereby enabling operation to be performed properly.

In particular, according to the present invention, even if the branch metric is set to a value of 0 at a point in time when undersampling occurs, the signal to be input to the branch metric calculation section is delayed by the delay unit, and at the next point in time at which the undersampling does not occur any more, the delayed signal is input to the branch metric calculation section so that the branch metric is calculated correctly, thereby ensuring proper operation.

### EFFECTS OF THE INVENTION

As described above, the maximum likelihood decoders and the information reproduction apparatuses according to the present invention ensure proper maximum likelihood decoding even if undersampling occurs.

### BRIEF DESCRIPTION OF DRAWINGS

FIG. 1 schematically illustrates the entire configuration of a read channel according to a first embodiment of the present invention.

FIG. 2 illustrates the internal configuration of a Viterbi decoder included in the read channel.

FIG. 3 shows an operation timing chart including times when undersampling occurs in the read channel.

FIG. 4 illustrates the internal configuration of a Viterbi decoder according to a second embodiment of the present invention.

FIG. 5 illustrates the internal configuration of a Viterbi decoder according to a third embodiment of the present invention.

FIG. 6 illustrates the internal configuration of a conventional Viterbi decoder.

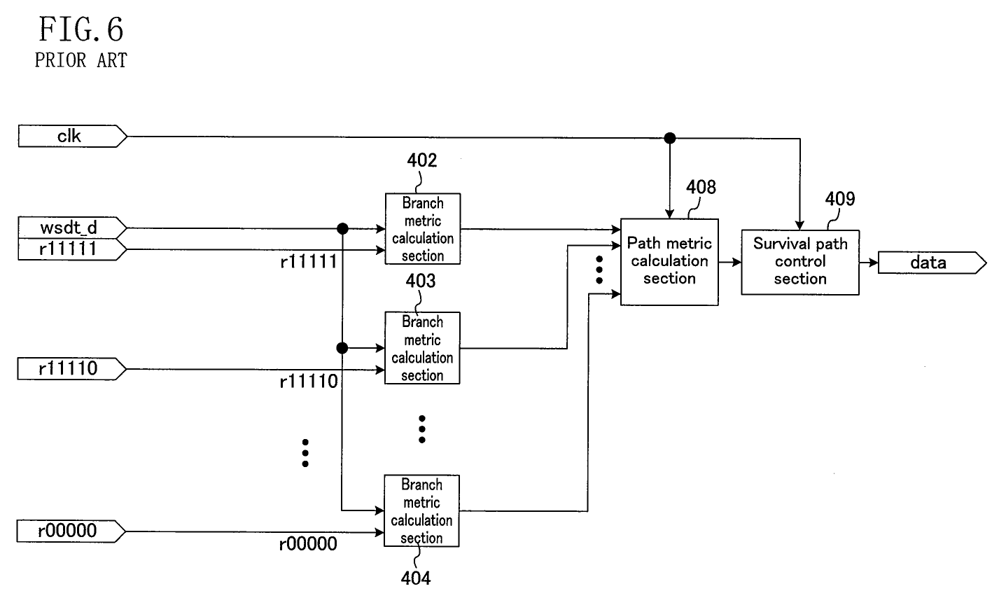

### EXPLANATION OF THE REFERENCE CHARACTERS

100 Read channel
101 Optical disk
102 Optical pickup (Read section)
103 Analog frontend (Analog waveform shaping section)
104 Analog-to-digital converter (Analog-to-digital converting section)
105 Clock generator (Clock generating section)
106 Waveform shaper (Digital signal shaping section)
107 Timing detector (Timing detecting section)
108 FIFO (Delay unit)
109, 109′, 109″ Viterbi decoders
201 Reference value generator (Reference value generating section)
202-204 Branch metric calculation sections
205-207 Selectors (Selecting sections)
208 Path metric calculation section (Path selection signal calculation section)
209 Survival path control section
300 Controller
301, 302 Comparators

### BEST MODE FOR CARRYING OUT THE INVENTION

Hereinafter, embodiments of the present invention will be described with reference to the accompanying drawings.

### First Embodiment

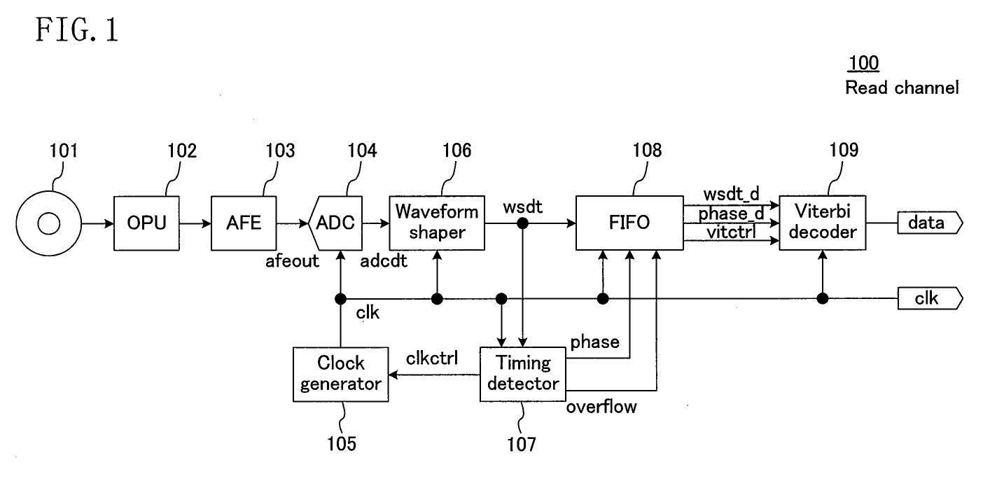

FIG. 1 schematically illustrates a read channel 100 as an information reproduction apparatus according to a first embodiment of the present invention. In FIG. 1, digital data is stored in an optical disk 101. In the read channel 100, this recorded data and a clock that is in synchronization with this recorded data are extracted. Although the optical disk 101 is used in this embodiment, the present invention is not limited to the optical disk 101, but is applicable to magnetic disks and magneto-optical disks and also to radio communication and wire communication.

Hereinafter, operation of the read channel 100 will be described in the order of signal flow. The digital data recorded on the optical disk 101 is read by an optical pickup (a read section) 102 and is then output as an analog signal containing recording-timing information. An analog frontend (an analog waveform shaping section) 103 performs analog processing, in which the amplitude and level of the analog signal from the optical pickup 102 are adjusted, a specific frequency band is emphasized or passed, and the like. Thereafter, an analog-to-digital converter (an analog-to-digital converting section) 104 performs sampling and quantization of the post-analog-processing analog signal from the analog frontend 103 to convert the analog signal to a digital signal containing the recording-timing information. A sampling clock clk which is input to the analog-to-digital converter 104 is generated by a clock generator (a clock generating section) 105. A waveform shaper (a digital signal shaping section) 106 performs digital processing, in which the amplitude and level of the digital signal from the analog-to-digital converter 104 are adjusted, a specific frequency band is emphasized or passed, and the like. For the sake of explanation, the output signal of the waveform shaper 106 will be hereinafter referred to as a “wsdt signal”.

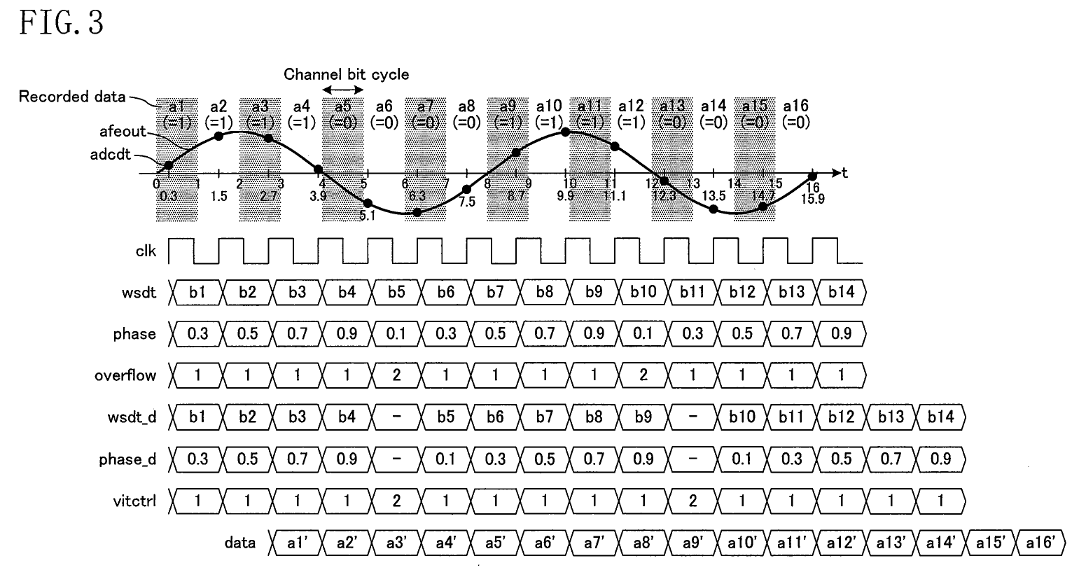

A timing detector (a timing detecting section) 107 uses the wsdt signal from the waveform shaper 106 to calculate phase information phase, overflow information overflow, and a clock generator control signal (a clock control signal) clkctrl. Detailed description of the calculation of these signals will be provided below with reference to FIG. 3. According to the clock generator control signal clkctrl from the timing detector 107, the clock generator 105 generates the clock signal clk whose cycle corresponds to the signal value of the clock generator control signal clkctrl. The timing detector 107 generates the clock generator control signal clkctrl in such a manner that the frequency of the clock clk generated by the clock generator 105 is higher than or equal to the recording-timing information recorded on the optical disk 101, that is, the channel frequency (the desired frequency).

A FIFO (a delay unit) 108 is a crucial element in the present invention. The FIFO 108, which is a first-in-first-out buffer, changes the delay of the wsdt signal from the waveform shaper 106 and the delay of the phase signal from the timing detector 107 in accordance with the overflow signal from the timing detector 107. The delayed signals are output as a wsdt_d signal and a phase_d signal. The FIFO 108 also changes the delay of the overflow signal from the timing detector 107, like the delay of the wsdt signal and the delay of the phase signal, and outputs the delayed signal as a Viterbi decoder control signal vitctrl. A Viterbi decoder 109 uses the wsdt_d signal (a first signal) containing the recording-timing information, the phase_d signal (a first phase signal), and the vitctrl signal (a first selection signal) from the FIFO 108 to perform maximum likelihood decoding based on the Viterbi algorithm, thereby outputting binary data data.

The binary data data signal is almost equal to the digital data recorded on the optical disk 101, but may contain some errors still remaining therein depending on the characteristics of the read channel 100. For example, if the quality of recording on the optical disk 101 is so inferior and hence beyond the error correction capability of the Viterbi decoder 109, data containing errors will be output as the binary data data signal. To address this, in a later stage in the read channel 100, the binary data data signal is subjected to error correction processing performed in accordance with the binary data data signal and the clk signal and using the Reed-Solomon decoding or other error correction method. Thereafter, an image or sound is created from the error-corrected digital data and is output from a display or speaker, or the error-corrected digital data is directly transmitted to a computer.

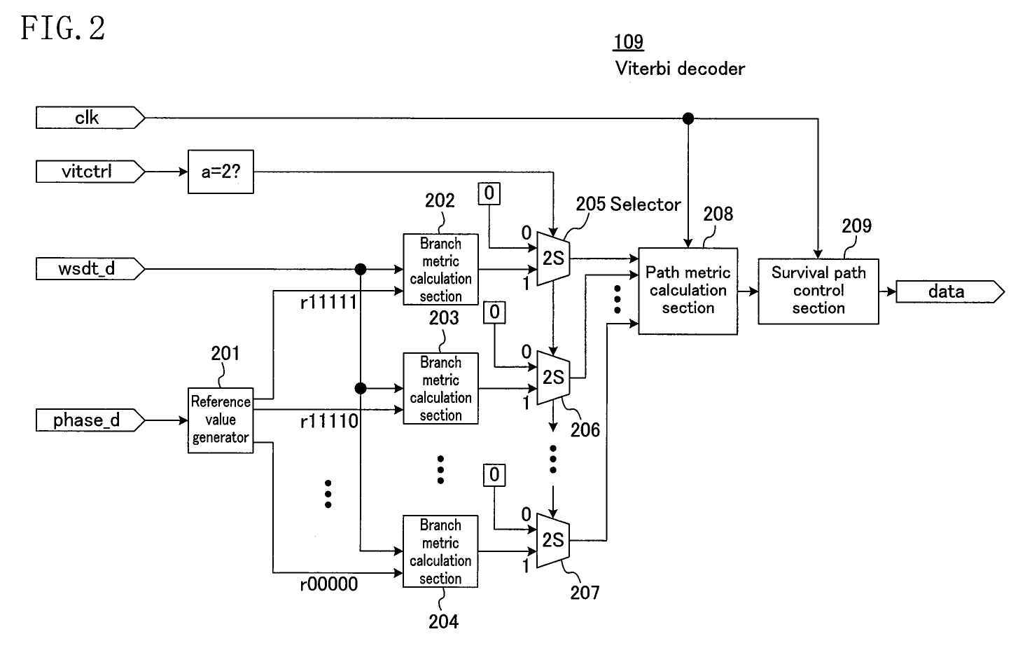

Next, the internal configuration of the Viterbi decoder 109 illustrated in FIG. 1 will be described with reference to FIG. 2.

In FIG. 2, each time a reference value generator 201 receives a piece of delay phase information phase_d from the FIFO 108, the reference value generator 201 generates a reference value for the Viterbi decoding in the phase indicated by that delay phase information phase_d. Specifically, this generation is performed by using reference values (expected values) in the two adjacent zero phases, one immediately before and one immediately after the phase indicated by that delay phase information phase_d, and obtaining a value between these two reference values by linear interpolation. In FIG. 2, a plurality of reference values r11111, r11110, . . . , r00000 are generated in accordance with successive pieces of delay phase information phase_d.

A plurality of branch metric calculation sections 202, 203, . . . , 204 each calculate a branch metric based on the digital signal wsdt_d from the FIFO 108 and on a corresponding one of the reference values from the reference value generator 201. The calculated branch metrics are basically output to a path metric calculation section 208 and used for generation of a path metric.

Selectors 205, 206, . . . , 207, which are important in the present invention, are provided between the branch metric calculation sections 202, 203, . . . , 204 and the path metric calculation section 208. These selectors 205, 206, . . . , 207 each select either the branch metric from a corresponding one of the branch metric calculation sections 202, 203, . . . , 204 or a value of 0. As a control signal for that selection, the Viterbi decoder control signal vitctrl from the FIFO 108 is input to each of the selectors 205, 206, . . . , 207. Under a specific condition in which the value of the Viterbi decoder control signal vitctrl is 2, each of the selectors 205, 206, . . . , 207 selects a value of 0 and forces the corresponding branch metric to be set to a value of 0.

The path metric calculation section (the path selection signal calculation section) 208 obtains a path metric in accordance with the branch metrics calculated by the branch metric calculation sections 202, 203, . . . , 204 or according to the branch metrics forced to be set to a value of 0, while at the same time obtaining a path selection signal. Only the path selection signal is output from the path metric calculation section 208. A survival path control section 209 obtains a survival path based on the path selection signal from the path metric calculation section 208 and outputs a code corresponding to that survival path as a data signal (a decoded value).

Next, FIG. 3 shows a timing chart including times at which undersampling occurs in the read channel 100 illustrated in FIG. 1.

In FIG. 3, items of digital data recorded on the optical disk 101 are denoted by a1 to a16. A specific value sequence in FIG. 3 is {1111000011110000}. An output signal afeout from the analog frontend 103 is an analog signal indicated by a solid line. The signal obtained by conversion of the analog signal afeout by the analog-to-digital converter 104 is an adcdt signal indicated by black circles in FIG. 3. The sampling clock in the analog-to-digital conversion is a clk signal. As can be seen from FIG. 3, this sampling clock signal clk is asynchronous to the channel bit cycles and the cycles of the clk signal are longer than the channel bit cycles, resulting in undersampling.

If each channel bit cycle has a period of 1.0, the analog signal afeout from the analog frontend 103 shown in FIG. 2 is an analog waveform from time 0 to time 16. In the case shown in FIG. 3, since each cycle of the clk signal has a period of 1.2 and the first rising edge occurs at time 0.3, all the rise times are {0.3, 1.5, 2.7, 3.9, 5.1, 6.3, 7.5, 8.7, 9.9, 11.1, 12.3, 13.5, 14.7, 15.9}. As shown in FIG. 3, the number of clock edges from the time 0 to the time 16 is only 14, which is two less than the 16 items of recorded data. The number of sampled values of the digital signal adcdt from the analog-to-digital converter 104 is naturally less by two.

The digital signal adcdt from the analog-to-digital converter 104 is shaped into the wsdt signal (a second signal) by the waveform shaper 106. In an actual circuit, a delay occurs in the shaping processing and in the pipeline processing, but in this timing chart, it is assumed, for the sake of explanation, that there are no such delays.

In FIG. 3, the phase information (a second phase signal) phase from the timing detector 107 is the phase of each rising edge of the clock signal clk with respect to the channel bit cycles. This phase equals the fractional portion of the time at which each rising edge occurs. For instance, the phase of the clk signal at the time at which the third rising edge thereof occurs in FIG. 3 is 2.7, and the fractional portion, which is 0.7, of the phase at this time is the phase information phase. Also in FIG. 3, the overflow signal from the timing detector 107 equals the difference between the integer parts of the phases of the clk signal at the times at which two successive rising edges thereof occur with respect to the channel bit cycles. For example, since the phases of the clk signal at the times at which the third and fourth rising edges thereof occur are 2.7 and 3.9 in FIG. 3, the difference, which is 1, between the integer parts of these two phases at these two points in time is the overflow signal. Also, in FIG. 3, since the phases of the clk signal at the times at which the fourth and fifth rising edges thereof occur are 3.9 and 5.1, the difference, which is 2, between the integer parts of these two phases at these two points in time is the overflow signal.

As can be seen from FIG. 3, undersampling occurs in the time period between the fourth and fifth rising edges of the clk signal, for example, because the time interval between the two items of digital data adcdt having phases 3.9 and 5.1, which are the phases at these two rising edges, exceeds the one channel bit cycle of the recorded data a5. The occurrence of this undersampling can be known by the fact that the value of the overflow signal changes from 1 to 2.

In an actual circuit, the phases of the rising edges of the clk signal are not known in advance. The timing detector 107 performs various kinds of processing so as to obtain, from the wsdt signal (the second signal) from the waveform shaper 106, the phase signal and the overflow signal that correspond to the wsdt signal.

In FIG. 3, the number of items of recorded data is greater than the number of the sampled values of the digital data wsdt signal. The number of clocks is 14, while the number of items of recorded data is 16. The FIFO 108 absorbs this difference in number. As already described, the FIFO 108 outputs the wsdt_d signal, the phase_d signal, and the vitctrl signal. Basically the wsdt_d signal, the phase_d signal, and the vitctrl signal are signals obtained just by delaying the wsdt signal from the waveform shaper 106, the phase signal and the overflow signal from the timing detector 107, respectively, but their delay varies depending on the value of the overflow signal. Specifically, as described previously, there is no rising edge of the clk signal in the channel bit cycle of the recorded data a5. In such a situation, the overflow signal changes in value from 1 to 2, and according to this value change in the overflow signal, the FIFO 108 generates the wsdt_d signal, the phase_d signal, and the vitctrl signal by adding one delay to the wsdt signal and to the phase signal (that is, by delaying the wsdt signal and the phase signal by one clock). In FIG. 3, since the undersampling occurring in the channel bit cycle of the recorded data a5 causes the value of the overflow signal to change to 2 in the channel bit cycle of the next recorded data a6, an arbitrary value (indicated by “−” in FIG. 3) is added and interpolated into the one clock between b4 and b5 of the wsdt_d signal and into the one clock between “0.9” and “0.1” of the phase_d signal, thereby producing delays. This arbitrary value may be the value (i.e., b4 and 0.9) immediately before the one clock or the value (i.e., b5 or 0.1) immediately after the one clock, or may be 0. Also, in the vitctrl signal, a value of 1 is added and interpolated in the channel bit cycle next to the channel bit cycle of the recorded data a6 in which the value of the overflow signal changes to 2, thereby producing a delay. In the example described above, the overflow signal changes in value from 1 to 2 in the channel bit cycle next to the channel bit cycle of the recorded data a6. When the overflow signal changes in value from 1 to 2 in the channel bit cycle of the recorded data a12, a delay is inserted in the same manner. Thus, the FIFO (the delay unit) 108 maintains the amount of delay, when the overflow signal from the timing detector 107 has a value of 1, that is, when the clock signal clk from the clock generator 21 equals the channel frequency. However, when the value of the overflow signal is changed to 2 and becomes lower than the channel frequency to cause undersampling, the FIFO 108 adds an arbitrary digital value and phase value to one clock of the wsdt_d signal and to one clock of the phased signal from the FIFO 108 so as to increase the amount of delay. On the other hand, when the value of the overflow signal is changed to 0 and becomes higher than the channel frequency to thereby cause oversampling to occur, the FIFO 108 operates in such a manner as to reduce the amount of delay.

The Viterbi decoder 109 performs maximum likelihood decoding by using the wsdt_d signal, the phase_d signal, and the vitctrl signal from the FIFO 108 and outputs the decoding results as the data signal. Before this data signal is output, there are delays, such as a pipeline delay in the branch metric calculation sections 202 to 204 and a memory length delay in the survival path control section 209, however, only a delay of two clocks is illustrated in FIG. 3.

Accordingly, in this embodiment, when undersampling occurs, the path metric and the path selection signal are generated based on the branch metrics having a value of 0 and interpolation is performed, whereby it is possible to make the number of items of data during operation equal to the number of channel bits, enabling the operation to be performed properly.

### Second Embodiment

Next, a second embodiment of the present invention will be described.

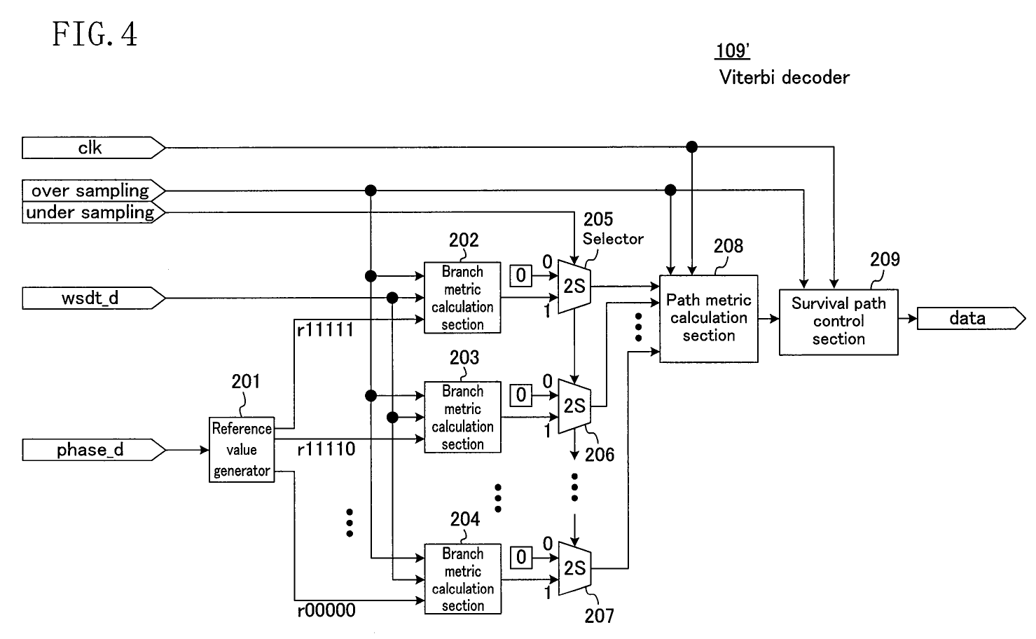

FIG. 4 illustrates the internal configuration of a Viterbi decoder 109′, which is an information reproduction apparatus according to the second embodiment of the present invention.

In the configuration of the Viterbi decoder 109′ illustrated in FIG. 4, the vitctrl signal shown in FIG. 2 is used as an undersampling signal, while an oversampling signal (a second selection signal) indicating the occurrence of oversampling of recorded data is input, and when this oversampling signal is received, branch metric calculation sections 202 to 204, a path metric calculation section 208, and a survival path control section 209 stop operating so as to change the branch metric calculation method, the path metric calculation method, and the data signal calculation method therein.

Hence, in this embodiment, proper operation is ensured not only when the recorded data is undersampled but also when oversampled.

### Third Embodiment

Next, a third embodiment of the present invention will be described.

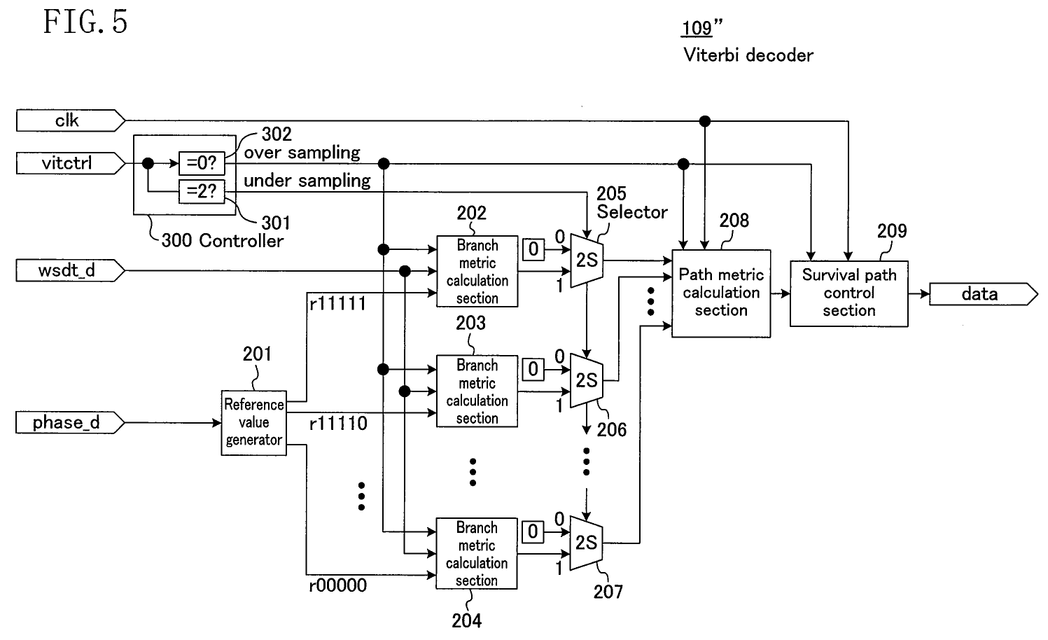

FIG. 5 illustrates the internal configuration of a Viterbi decoder 109″, which is an information reproduction apparatus according to the third embodiment of the present invention. In the second embodiment, the oversampling signal, and the undersampling signal (the vitctrl signal) from the FIFO 108 are input. In this embodiment, the Viterbi decoder 109″ is configured so as to receive a vitctrl signal (a Viterbi decoding control signal) alone and generate an oversampling signal.

To be specific, in FIG. 5, a controller 300 is added, which receives the vitctrl signal from the FIFO 108 and generates an undersampling signal and an oversampling signal. In view of the fact that the vitctrl signal from the FIFO 108 changes in value from 1 to 2 as described above when undersampling occurs, and changes in the opposite way from 1 to 0 when oversampling occurs, the controller 300 is configured so as to include a first comparator 301 for comparing the value of the vitctrl signal with a value of 2 and a second comparator 302 for comparing the value of the vitctrl signal with a value of 0, and so as to generate and output an undersampling signal having a value of 1 when the vitctrl signal=2, and generate and output an oversampling signal having a value of 1 when the vitctrl signal=0.

In the foregoing description, the frequency of the clock signal clk generated by the clock generator 105 is controlled so as to be higher than or equal to the channel frequency. However, even in a case where data is read from the optical disk 101 at a frequency which is an integral multiple or an integral submultiple of the channel frequency, in accordance with the type of control, such as constant angular velocity control, there is a situation in which undersampling occur. The present invention is thus applicable to such a case.

### INDUSTRIAL APPLICABILITY

As described above, the present invention, which ensures proper maximum likelihood decoding even if undersampling occurs, is applicable to maximum likelihood decoders, information reproduction apparatuses and the like for reproducing data recorded on an optical disk, a magneto-optical disk, a magnetic disk, or the like.

1. A maximum likelihood decoder comprising:
a branch metric calculation section for receiving a first signal containing recording-timing information, and calculating a branch metric based on the first input signal and on a reference value for use in maximum likelihood decoding;
a path selection signal calculation section for calculating a path selection signal based on the branch metric calculated by the branch metric calculation section;
a survival path control section for calculating a decoded value by performing maximum likelihood decoding of the first input signal in accordance with the path selection signal calculated by the path selection signal calculation section; and
a selecting section for receiving a first selection signal instructing selection of either the branch metric of the branch metric calculation section or a value “0” and performing selection in accordance with the first selection signal,
wherein the path selection signal calculation section receives either the branch metric of the branch metric calculation section or the value “0” selected by the selecting section, and calculates the path selection signal based on the received branch metric or value “0”.

2. The maximum likelihood decoder of claim 1, comprising a reference value generating section for receiving a first phase signal and generating a reference value for Viterbi decoding in a phase indicated by the first phase signal, in accordance with the first phase signal and reference values in two adjacent zero phases immediately before and after the phase indicated by the first phase signal.

3. The maximum likelihood decoder of claim 1, wherein the branch metric calculation section, the path selection signal calculation section, and the survival path control section receive a second selection signal instructing change of a branch metric calculation method, a path selection signal calculation method, and a survival path control method and perform operations in accordance with the second selection signal.

4. The maximum likelihood decoder of claim 1, wherein the first selection signal input to the selecting section is an undersampling signal output when undersampling of recorded data occurs; and
the selecting section, upon receipt of the undersampling signal, selects the value “0”.

5. The maximum likelihood decoder of claim 3, wherein the second selection signal is an oversampling signal output when oversampling of recorded data occurs; and
the branch metric calculation section, the path selection signal calculation section, and the survival path control section, upon receipt of the oversampling signal, each stop operating.

6. The maximum likelihood decoder of claim 3, comprising a reference value generating section for receiving a first phase signal and generating a reference value for Viterbi decoding in a phase indicated by the first phase signal, in accordance with the first phase signal and reference values in two adjacent zero phases immediately before and after the phase indicated by the first phase signal.

7. The maximum likelihood decoder of claim 3, comprising a controller for receiving a Viterbi decoder control signal and generating the first and second selection signals based on the Viterbi decoder control signal.

8. The maximum likelihood decoder of claim 1, comprising:
a timing detecting section for receiving a second signal containing the recording-timing information and a clock signal, outputting, as a second phase signal, a phase difference between the recording-timing information contained in the second input signal and the clock signal in accordance with the second input signal and the clock signal, and generating an overflow signal having a predetermined value each time the second phase signal exceeds a channel cycle indicated by the recording-timing information by one cycle or multiple cycles; and
a delay unit for delaying the second input signal and the second phase signal in accordance with a certain amount of delay corresponding to the value of the overflow signal generated by the timing detecting section, and outputting the delayed signals as the first input signal and as a first phase signal, while outputting a Viterbi decoder control signal.

9. An information reproduction apparatus comprising:
the maximum likelihood decoder of claim 8;
a read section for reading data recorded on a recording medium as an analog signal;
an analog waveform shaping section for shaping the analog signal read by the read section;
an analog-to-digital converting section for converting the analog signal shaped by the analog waveform shaping section to a digital signal in accordance with timing provided by the clock signal;
a clock generating section for receiving a clock control signal and generating the clock signal having a certain cycle based on the clock control signal; and
a digital signal shaping section for shaping the digital signal converted by the analog-to-digital converting section and outputting the shaped signal as the second input signal to the timing detecting section,
wherein the timing detecting section in the maximum likelihood decoder also generates the clock control signal.

10. The information reproduction apparatus of claim 9, wherein the timing detecting section generates the clock control signal so that the clock signal generated by the clock generating section has a frequency higher than a desired frequency.

11. The information reproduction apparatus of claim 9, wherein the timing detecting section generates the clock control signal so that the clock signal generated by the clock generating section has a frequency equal to a desired frequency.

12. The information reproduction apparatus of claim 9, wherein the delay unit included in the maximum likelihood decoder reduces an amount of delay when the clock signal has a frequency higher than a desired frequency, maintains the amount of delay when the clock signal has a frequency equal to the desired frequency, and increases the amount of delay when the clock signal has a frequency lower than the desired frequency.

13. The information reproduction apparatus of any one of claims 10 to 12, wherein the desired frequency is a channel frequency.

14. The information reproduction apparatus of any one of claims 10 to 12, wherein the desired frequency is a frequency which is an integral multiple of a channel frequency.

15. The information reproduction apparatus of any one of claims 10 to 12, wherein the desired frequency is a frequency which is an integral submultiple of a channel frequency.

16. The information reproduction apparatus of any one of claims 9 to 15, wherein the first input signal is a signal reproduced from an optical disk.

17. The information reproduction apparatus of any one of claims 9 to 15, wherein the first input signal is a signal reproduced from a magneto-optical disk.

18. The information reproduction apparatus of any one of claims 9 to 15, wherein the first input signal is a signal reproduced from a magnetic disk.
